(19) United States
(12) Patent Application Publication
(10) Pub. No.: US 2010/0308418 A1
(43) Pub. Date: Dec. 9, 2010

(54) Semiconductor Devices and Methods of Manufacture Thereof

(76) Inventors: Knut Stahrenberg, Wappingers Falls, NY (US); Roland Hampp, Bad Abbach (DE); Jin-Ping Han, Fishkill, NY (US); Klaus von Arnim, Munich (DE)

Correspondence Address: SLATER & MATSIL, L.L.P., 17950 PRESTON ROAD, SUITE 1000, DALLAS, TX, 75252, US

(21) Appl. No.: 12/481,373

(22) Filed: Jun. 9, 2009

(51) Int. Cl. H01L 27/088; H01L 21/8238

(52) U.S. Cl. 257/392; 438/217; 257/E27.061; 257/E21.632

(57) ABSTRACT

Semiconductor devices and methods of manufacture thereof are disclosed. In one embodiment, a semiconductor device includes a first transistor having a gate dielectric and a cap layer disposed over the gate dielectric. The first transistor includes a gate including a metal layer disposed over the cap layer and a semiconductive material disposed over the metal layer. The semiconductor device includes a second transistor in a second region of the workpiece, which includes the gate dielectric and the cap layer disposed over the gate dielectric. The second transistor includes a gate that includes the metal layer disposed over the cap layer and the semiconductive material disposed over the metal layer. A thickness of the metal layer, a thickness of the semiconductive material, an implantation region of a channel region, or a doped region of the gate dielectric of the first transistor achieves a predetermined threshold voltage for the first transistor.

### TECHNICAL FIELD

The present invention relates generally to semiconductor devices, and more particularly to the fabrication of transistors.

### BACKGROUND

Semiconductor devices are used in a variety of electronic applications, such as personal computers, cell phones, digital cameras, and other electronic equipment, as examples. Semiconductor devices are typically fabricated by sequentially depositing insulating or dielectric layers, conductive layers, and semiconductive layers of material over a semiconductor substrate, and patterning the various layers using lithography to form circuit components and elements thereon.

A transistor is an element that is used frequently in semiconductor devices. There may be millions of transistors on a single integrated circuit (IC), for example. A common type of transistor used in semiconductor device fabrication is a metal oxide semiconductor field effect transistor (MOSFET), as an example. A transistor typically includes a gate dielectric disposed over a channel region in a substrate, and a gate electrode formed over the gate dielectric. A source region and a drain region are formed on either side of the channel region within the substrate.

Complementary metal oxide semiconductor (CMOS) devices include both p-channel and n-channel transistors, e.g., a p-channel metal oxide semiconductor (PMOS) transistor and an n-channel metal oxide semiconductor (NMOS) transistor, arranged in complementary configurations. The PMOS and NMOS transistors of CMOS devices in many applications require symmetric threshold voltages (Vₜ), e.g., where the threshold voltages of the PMOS and NMOS transistors have equal yet opposite magnitudes. Manufacturing CMOS devices requires additional manufacturing steps and material layers to tune the threshold voltages of the PMOS and NMOS transistors, and is therefore more costly and complex than manufacturing a single type of transistor.

Thus, what are needed in the art are improved methods of fabricating semiconductors having two or more types of transistors and structures thereof.

### SUMMARY OF THE INVENTION

These and other problems are generally solved or circumvented, and technical advantages are generally achieved, by embodiments of the present invention, which provide novel methods of manufacturing semiconductor devices and structures thereof.

In accordance with one embodiment, a semiconductor device includes a first transistor in a first region of a workpiece. The first transistor includes a gate dielectric and a cap layer disposed over the gate dielectric. The first transistor includes a gate including a metal layer disposed over the cap layer and a semiconductive material disposed over the metal layer. The semiconductor device also includes a second transistor in a second region of the workpiece. The second transistor includes the gate dielectric and the cap layer disposed over the gate dielectric. The second transistor includes a gate that includes the metal layer disposed over the cap layer and the semiconductive material disposed over the metal layer. A thickness of the metal layer, a thickness of the semiconductive material, an implantation region of a channel region, or a doped region of the gate dielectric of the first transistor achieves a predetermined threshold voltage for the first transistor.

The foregoing has outlined rather broadly the features and technical advantages of embodiments of the present invention in order that the detailed description of the invention that follows may be better understood. Additional features and advantages of embodiments of the invention will be described hereinafter, which form the subject of the claims of the invention. It should be appreciated by those skilled in the art that the conception and specific embodiments disclosed may be readily utilized as a basis for modifying or designing other structures or processes for carrying out the same purposes of the present invention. It should also be realized by those skilled in the art that such equivalent constructions do not depart from the spirit and scope of the invention as set forth in the appended claims.

### BRIEF DESCRIPTION OF THE DRAWINGS

For a more complete understanding of the present invention, and the advantages thereof, reference is now made to the following descriptions taken in conjunction with the accompanying drawings, in which:

FIG. 1 is a cross-sectional view of a semiconductor device in accordance with an embodiment of the present invention, wherein a first transistor is formed in a first region of a workpiece and a second transistor is formed in a second region of the workpiece, the first transistor and the second transistor including a single cap layer comprised of the same material;

FIG. 2 is a graph illustrating an effect on the threshold voltage of various thicknesses of a metal layer of a transistor;

FIGS. 3 through 9 show cross-sectional views of a method of manufacturing a semiconductor device at various stages in accordance with an embodiment of the present invention; and

FIG. 10 shows a cross-sectional view of an embodiment of the present invention, wherein a thickness of a metal layer, a thickness of a semiconductive material, an implantation region of a channel region, or a doped region of a gate dielectric achieves a predetermined threshold voltage for the first transistor.

Corresponding numerals and symbols in the different figures generally refer to corresponding parts unless otherwise indicated. The figures are drawn to clearly illustrate the relevant aspects of the preferred embodiments and are not necessarily drawn to scale.

### DETAILED DESCRIPTION OF ILLUSTRATIVE EMBODIMENTS

The making and using of the presently preferred embodiments are discussed in detail below. It should be appreciated, however, that the present invention provides many applicable inventive concepts that can be embodied in a wide variety of specific contexts. The specific embodiments discussed are merely illustrative of specific ways to make and use the invention, and do not limit the scope of the invention.

As features of semiconductor devices are decreased in size, as is the trend in the semiconductor industry, it becomes important to avoid or minimize depletion effects of transistor gate electrodes. Depletion effects may restrict the formation of an inversion layer and thus may limit electrical performance of a semiconductor device. To avoid depletion effects, additional material layers have begun to be implemented in gate stacks of transistors.

For example, one recent trend in CMOS devices is the use of a high dielectric constant (k) material as a gate dielectric combined with the use of a metal gate material. However, to achieve the desired band-edge work functions and tune the threshold voltages of high k/metal gate CMOS devices, complex gate stacks and processing are required. The use of a thin single capping layer on top of the high k gate dielectric material of the NMOS transistor is known to shift the NMOS transistor work function to the band edge. The capping layers used on NMOS transistors are typically lanthanide series-based metals or metal-oxides. However, in this approach, the capping layer is required to be stripped from the PMOS transistors, which can cause problems.

Another approach for tuning threshold voltages of high k/metal gate CMOS devices is to use two independently integrated cap layers: lanthanide-based metal or metal oxide cap layers for the NMOS transistors and aluminum-based cap layers for the PMOS transistors, as examples. This approach results in stacked cap layers on the NMOS transistors and a single cap layer on the PMOS transistors, together with multiple metal layers for the PMOS transistor gates. The multiple metal layers of the PMOS transistor gate create several interfaces in the gate stack, add a great amount of complexity and cost to the process flow, and result in gate stacks of the PMOS and NMOS transistors having different final heights.

Thus, improved methods of tuning the threshold voltages of transistors of semiconductor devices are needed in the art.

Embodiments of the present invention provide novel methods of fabricating transistor devices, wherein threshold voltage levels are established and tuned for multiple transistors across a surface of a semiconductor device. A single cap layer comprising an aluminum-containing material or TiOₓN_{y} is formed on both the PMOS and NMOS transistors of a CMOS device. The manufacturing process requires fewer processing steps and a less complex process flow. Only one cap layer is required, and multiple metal layers are not required in the PMOS transistor gates. The cap layer establishes the threshold voltage of the PMOS transistors, and the threshold voltage of the NMOS transistors is established or adjusted using a thickness of a gate material layer, an implantation process of a channel region of the NMOS transistors, and/or a doped region of a gate dielectric of the NMOS transistors, to be described further herein.

The present invention will be described with respect to preferred embodiments in specific contexts, namely implemented in semiconductor devices including a plurality of NMOS or PMOS transistors. Embodiments of the invention may be implemented in semiconductor applications such as memory devices, logic devices, CMOS devices, and other applications that utilize transistor devices, for example.

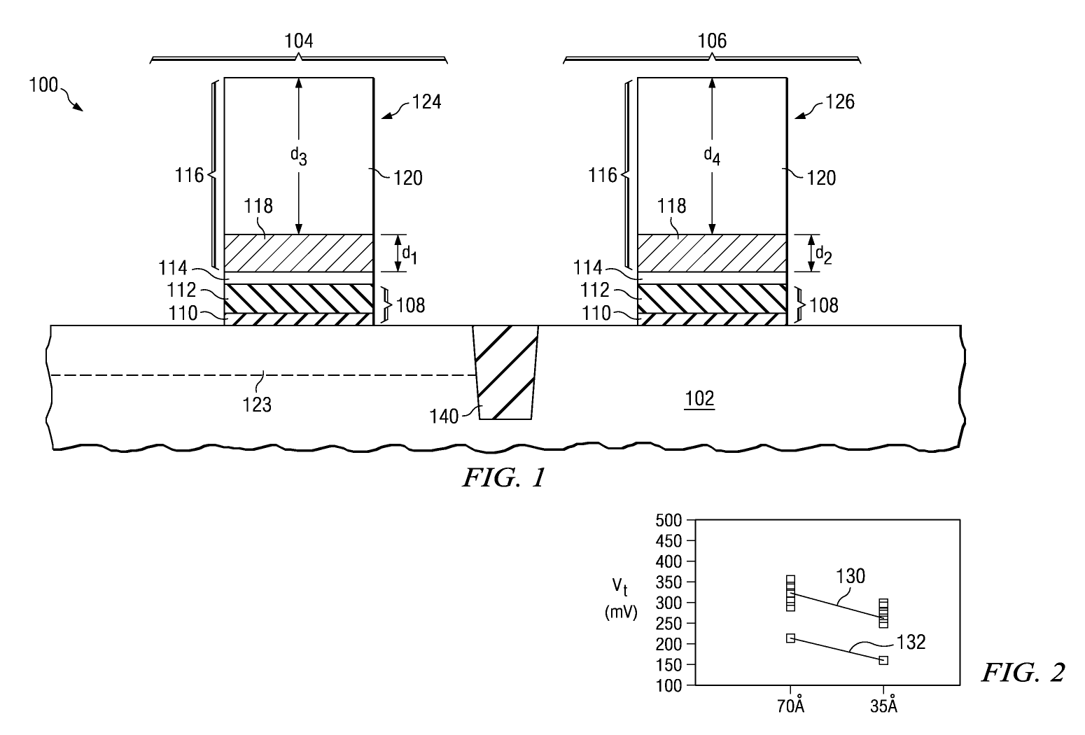

FIG. 1 is a cross-sectional view of a semiconductor device 100 in accordance with an embodiment of the present invention, wherein a first transistor 124 is formed in a first region 104 of a workpiece 102 and a second transistor 126 is formed in a second region 106 of the workpiece 102. The first transistor 124 comprises an NMOS transistor and the second transistor 126 comprises a PMOS transistor. An optional implantation region 123 may be implanted into the channel region of the NMOS transistor 124 to tune the threshold voltage of the NMOS transistor 124, e.g., by implanting As or P into the workpiece 102 in the first region 104 (e.g., while masking other regions 106 of the workpiece 102) prior to depositing the gate dielectric material 108. An isolation region 140 may be formed in the workpiece 102 between the two transistors 124 and 126.

The gate dielectric 108 of both transistors 124 and 126 may comprise a first insulating layer 110 and a second insulating layer 112 disposed over the first insulating layer 110. The second insulating layer 112 may include an optional doped region in the first transistor 124 for tuning the threshold voltage of the first transistor 124. A cap layer 114 is disposed over the gate dielectric 108 of the transistors 124 and 126.

The gates 116 of the transistors 124 and 126 comprise a metal layer 118 disposed over the cap layer 114 and a semiconductive material layer 120 disposed over the metal layer 118. The thickness d₁ of the metal layer 118 of the first transistor 124 may comprise a different thickness or the same thickness as the thickness d₂ of the metal layer 118 of the second transistor 126. The thickness d₃ of the semiconductive material layer 120 of the first transistor 124 may comprise a different thickness or the same thickness as the thickness d₄ of the semiconductive material layer 120 of the second transistor 126.

In accordance with embodiments of the present invention, the thickness and material selection of the cap layer 114 is used to establish the threshold voltage (Vₜ) of the second transistor 126 in the second region 106. The threshold voltage of the first transistor 124 in the first region 104 may be tuned or established using the implantation region 123 in the channel region, by altering the thickness d₁ of the metal layer 118 of the gate 116, by altering the thickness d₃ of the semiconductive material 120 of the gate 116, by forming a doped region in the second insulating layer 112 of the dielectric material 108, or one or more combinations thereof. One or more of these four features of the first transistor 124 may be altered to achieve a predetermined threshold voltage, e.g., a desired threshold voltage for the first transistor 124, depending on the application, for example.

FIG. 2 is a graph illustrating an effect on the threshold voltage of various thicknesses of a metal layer 118 of a transistor 124 or 126. The graph at 130 shows threshold voltages for a metal layer 118 comprising TiN at two thicknesses, 70 Å and 35 Å, for a long channel transistor 124. The graph at 132 shows threshold voltages for a metal layer 118 at the two thicknesses for a shorter channel transistor 124. The graphs 130 and 132 illustrate that reducing the thickness d₁ of the metal layer 118 in a first region 104 results in a reduction of the threshold voltage of the first transistor 124.

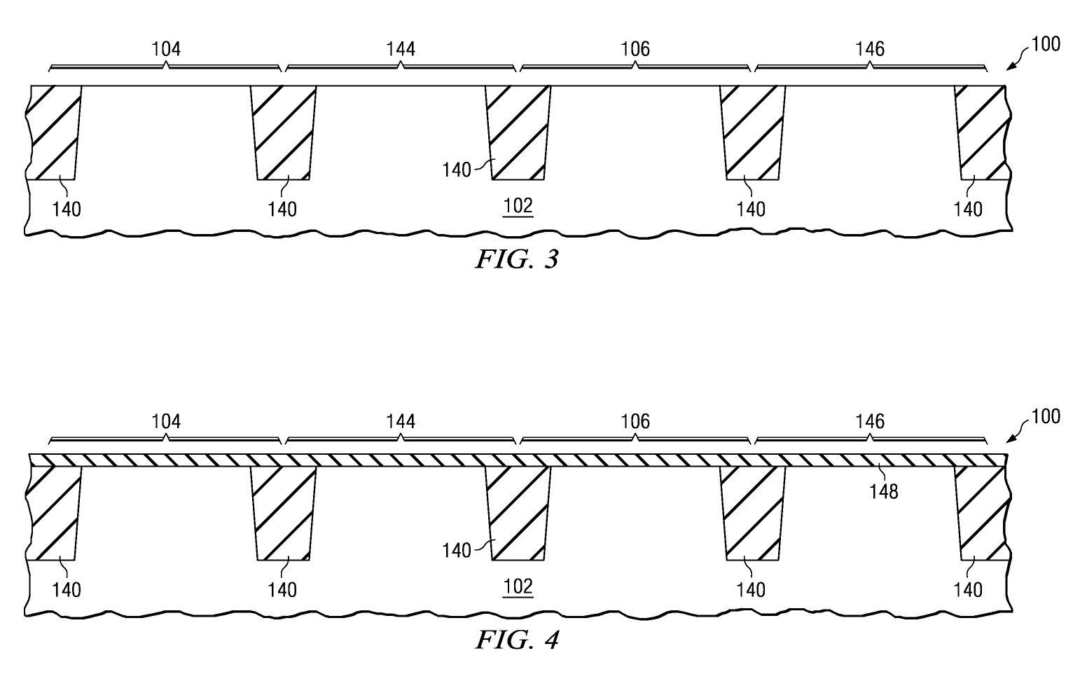

FIGS. 3 through 9 show cross-sectional views of a method of manufacturing a semiconductor device 100 at various stages in accordance with an embodiment of the present invention. To manufacture the semiconductor device 100, first, a workpiece 102 is provided. The workpiece 102 may include a semiconductor substrate comprising silicon or other semiconductor materials and may be covered by an insulating layer, for example. The workpiece 102 may also include other active components or circuits, not shown. The workpiece 102 may comprise silicon oxide over single-crystal silicon, for example. The workpiece 102 may include other conductive layers or other semiconductor elements, e.g., transistors, diodes, etc. Compound semiconductors, GaAs, InP, Si/Ge, or SiC, as examples, may be used in place of silicon. The workpiece 102 may comprise a silicon-on-insulator (SOI) or a germanium-on-insulator (GOI) substrate, as examples.

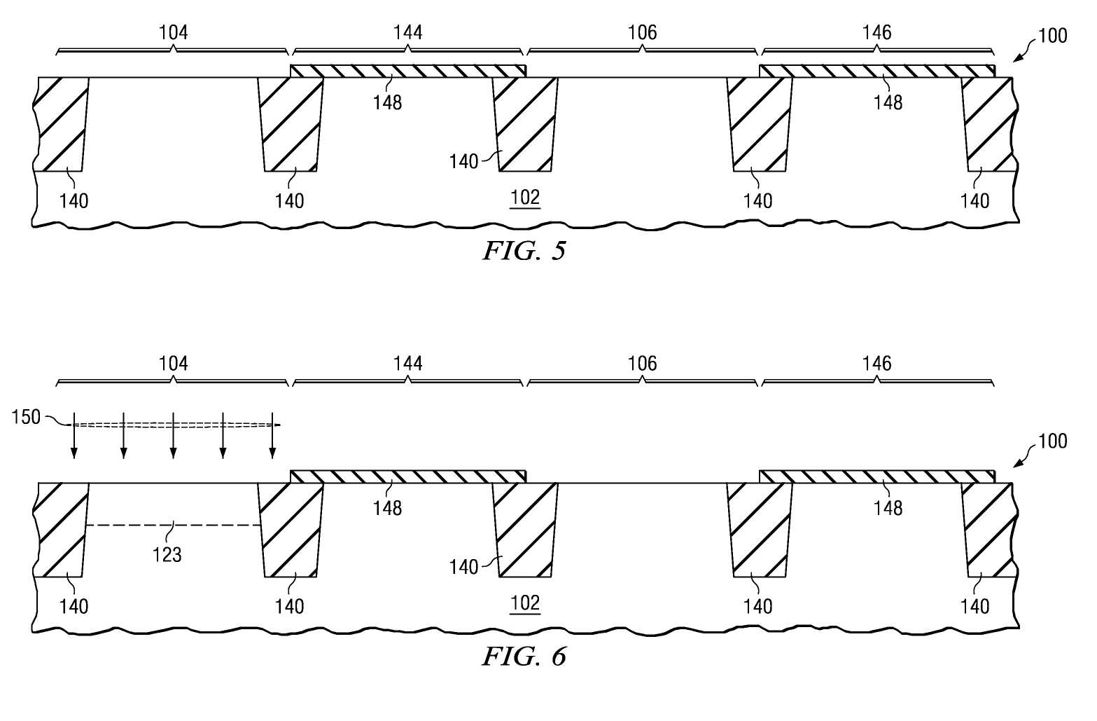

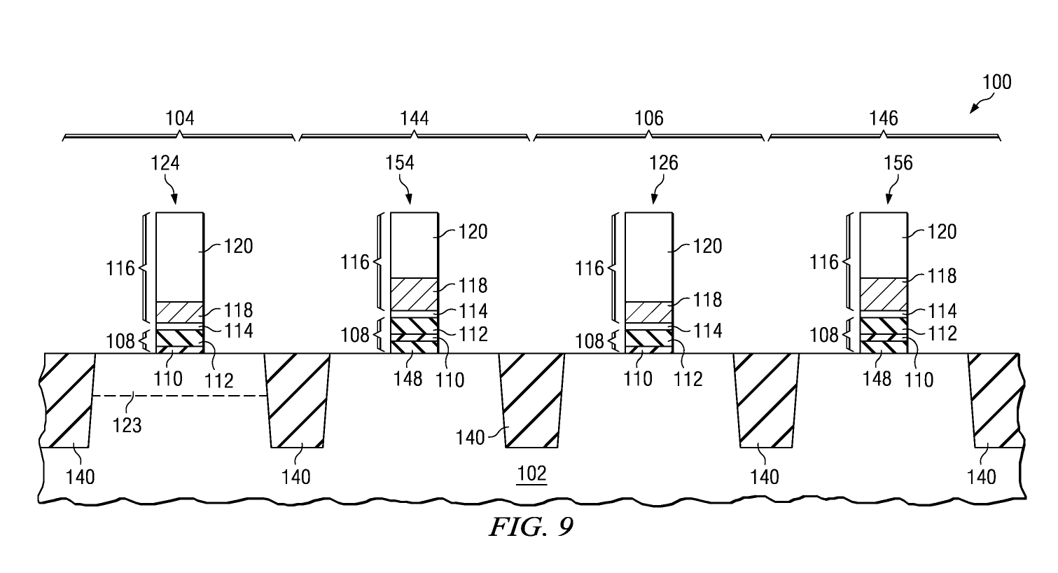

The workpiece 102 comprises a first region 104 and a second region 106 in which a first transistor 124 and a second transistor 126, respectively (see FIG. 9) will be formed. In the embodiment shown, the workpiece 102 also includes a third region 144 and a fourth region 146 in which a third transistor 154 and a fourth transistor 156, respectively (see FIG. 9) will also be formed. The third transistor 154 and fourth transistor 156 are optional and may not be included in the semiconductor device 100. The third transistor 154 and fourth transistor 156 may comprise transistors that require a thicker gate dielectric; thus, the optional additional manufacturing steps shown in FIGS. 4 and 5 may be included in the process flow. The third and fourth transistors 154 and 156 may comprise higher voltage transistors that require thicker gate dielectric 108 materials, for example. Additional transistors (not shown) may also be formed on the semiconductor device 100 that require different thicknesses of gate dielectric materials in accordance with embodiments of the invention, for example.

A plurality of isolation regions 140 are formed in the workpiece 102, as shown in FIG. 3. The isolation regions 140 may comprise shallow trench isolation (STI) regions, deep trench (DT) isolation regions, field oxide (FOX) isolation regions, or other insulating regions, as examples. The isolation regions 140 may be formed by etching trenches in the workpiece 100 using lithography and filling the trenches with one or more insulating materials, for example.

As one example, the isolation regions 140 may be formed by depositing a hard mask (not shown) over the workpiece 102 and forming trenches in the workpiece 102 and the hard mask using a lithography process. The isolation regions 140 may be formed by depositing a photoresist over the hard mask, patterning the photoresist using a lithography mask and an exposure process, developing the photoresist, removing portions of the photoresist, and then using the photoresist and/or hard mask to protect portions of the workpiece 102 while other portions are etched away, forming trenches in the workpiece 102. The photoresist is removed, and the trenches are then filled with an insulating material such as an oxide or nitride, or multiple layers and combinations thereof, as examples. The hard mask may then be removed. Alternatively, the isolation regions 140 may be formed using other methods and may be filled with other materials.

The workpiece 102 may be implanted with well regions, e.g., using As, B, P, or other dopant materials in the first region 104, the second region 106, the third region 144, and the fourth region 146. Portions of the workpiece 102 may be masked while each region or groups of regions 104, 106, 144, or 146 are implanted with dopants to form the particular well regions required for the various types of transistors 124, 126, 154, and 156 to be fabricated in each region 104, 106, 144, and 146, for example. The well region implantation processes may be adjusted or selected to tailor or affect the threshold voltages of transistors 124, 126, 154, and 156 to be fabricated in each region 104, 106, 144, and 146, in some embodiments, for example. Hard masks and/or photoresists (not shown) used during the implantation of the well regions are then removed.

An optional dielectric layer 148 may be formed over the workpiece 102 and isolation regions 140, if the semiconductor device 100 will include third and fourth transistors 154 and 156 in the third and fourth regions 144 and 146, as shown in FIG. 4. The optional dielectric layer 148 may comprise about 40 to 80 Å of silicon dioxide as-deposited. The thickness of the dielectric layer 148 may be reduced in subsequent processing of the semiconductor device 100, for example. The dielectric layer 148 may comprise a high temperature oxide (HTO) deposited at a temperature of about 750 degrees C., as an example. Alternatively, the dielectric layer 148 may comprise other oxides, nitrides, or other insulating materials deposited using other methods and at other thicknesses and temperatures, for example.

The optional dielectric layer 148 is removed from the first region 104, the second region 106, and other regions where the dielectric layer 148 is not required using lithography, as shown in FIG. 5. A photoresist and optional hard mask (not shown) may be deposited over the workpiece 102 and patterned, and then the photoresist and/or hard mask are used as an etch mask while portions of the dielectric layer 148 are etched away.

An optional implantation process 150 may be used to implant the workpiece 102 with a substance in the first region 104, as shown in FIG. 6. A masking material such as a photoresist may be formed over the workpiece 102, and the masking material may be patterned to expose the first region 104, for example, not shown. The substance implanted may comprise an impurity or dopant such as As or P, forming an implantation region 123 in the channel region of the first transistor 124 that is used to tune the work function and threshold voltage of the first transistor 124 in the first region 104, for example. Alternatively, other substances may be implanted to alter or adjust the work function of the first transistor 124 in the first region 104. In some embodiments of the present invention, the implantation process 150 and formation of the implantation region 123 in the first region 104 may not be included in the process flow.

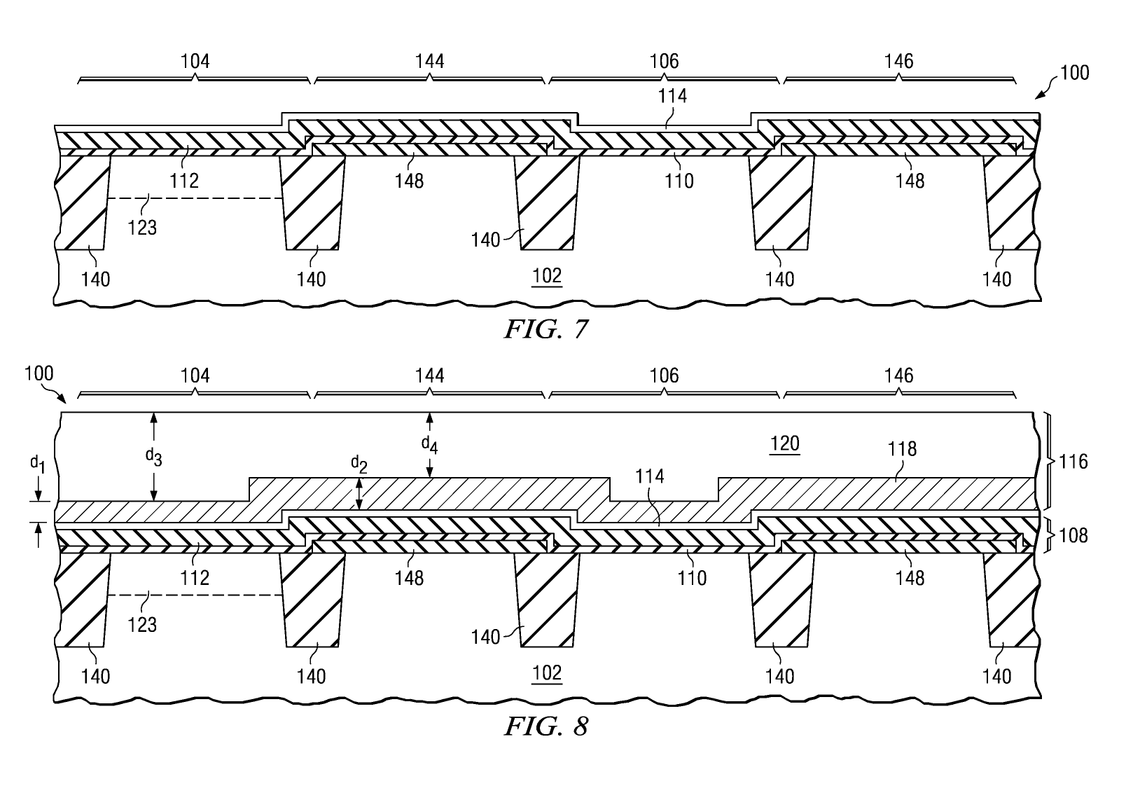

A first insulating layer 110 is formed over the workpiece 102 in the first region 104 and the second region 106, and over the dielectric layer 148 in the third region 144 and the fourth region 146, as shown in FIG. 7. The first insulating layer 110 is optional and may not be included in some embodiments, for example. The optional first insulating layer 110 may function as an interfacial layer that improves the quality of the interface of a second insulating layer 112 to the workpiece 102. In some embodiments, the first insulating layer 110 may comprise a thin layer of silicon oxynitride (SiON) comprising a thickness of about 20 Å or less, for example. Alternatively, the first insulating layer 110 may comprise other materials and dimensions. The first insulating layer 110 may be formed by a furnace oxidization process in the presence of nitrogen or using a rapid thermal (RT) process, as examples, although the first insulating layer 110 may be formed using other methods.

A second insulating layer 112 is deposited over the first insulating layer 110, if present, or over the workpiece 102, if the first insulating layer 110 is not included. The second insulating layer 112 may comprise at least one high k dielectric material layer comprising hafnium, for example, although alternatively, other high k dielectric materials may also be used. The second insulating layer 112 may comprise about 50 Å or less of a high-k dielectric material having a dielectric constant or k value of greater than about 3.9, such as a hafnium-based dielectric material (e.g., HfSiON, HfO, or HfSiO), a doped hafnium-based dielectric material, a Zr-based dielectric material, TiO₂, Ta₂O₅, Sc₂O₃, Y₂O₃, CeO₂, LaAlO₃, SrTiO₃, SrZrO₃, BaTiO₃, other high-k dielectric materials, or combinations and multiple layers thereof, as examples. Alternatively, the second insulating layer 112 may comprise other dimensions and materials, for example. The second insulating layer 112 may be formed using thermal oxidation, chemical vapor deposition (CVD), atomic layer deposition (ALD), metal organic chemical vapor deposition (MOCVD), physical vapor deposition (PVD), or jet vapor deposition (JVD), as examples, although alternatively, other methods may also be used to form the second insulating layer 112.

An optional doping process may be used to dope the insulating layer 112 in the NMOS region, e.g., in the first region 104, with a lanthanide series-based metal to tune the work-function of the first transistor 124 in the first region 104. A masking material such as a photoresist may be formed over the workpiece 102, and the masking material may be patterned to expose the first region 104, for example, not shown. The doping process may comprise an ion implantation and/or diffusion process, for example. The lanthanide series-based metal may comprise La, LaO, or other metals or metal oxides, as examples. The lanthanide series-based metal may be implanted and then the semiconductor device 100 may be annealed to diffuse the lanthanide series-based metal into the high k dielectric material of the second insulating layer 112, for example. The optional doped region in the second insulating layer 112 of the first transistor 124 may be used to tune the work function of the first transistor 124 in some embodiments, for example. Alternatively, the optional doped region of the second insulating layer 112 of the first transistor 124 in the first region 104 may not be included.

A cap layer 114 is then formed over the second insulating layer 112, as shown in FIG. 7. The cap layer 114 may comprise about 6 Å less of an aluminum-containing material, such as Al, Al₂O₃, AlN, or AlOₓN_{y}, or the cap layer 114 may comprise TiOₓN_{y}, as examples. Alternatively, the cap layer 114 may comprise other materials and dimensions. The cap layer 114 comprises the same material for the first transistor 124 formed in the first region 104 and the second transistor 126 in the second region 106. The cap layer 114 may also comprise the same material for the third transistor 154 formed in the third region 144 and the fourth transistor 156 formed in the fourth region 146 as the material of the cap layer 114 in the first and second regions 104 and 106, for example.

The type of material and the thickness of the cap layer 114 has an effect on the threshold voltage of the second transistor 126 formed in the second region 106. In some embodiments, the cap layer 114 material and thickness is selected to achieve or establish a predetermined threshold voltage for the second transistor 126. The cap layer 114 material and thickness also may have an effect on the threshold voltages of other transistors 124, 154, and 156 formed in the first region 104, second region 144, and third region 146. Other parameters of the transistors 124, 154, and 156 may be altered to offset or accommodate for the effect of the cap layer 114 on the threshold voltages, such as by forming implantation region 123 (see FIG. 1), by altering a thickness of a subsequently deposited metal layer 118 and/or semiconductive material 120 of a gate 116, and/or by forming a doped region in the gate dielectric 108, for example, to be described further herein.

The thickness of the cap layer 114 may be the same for all transistors 124, 126, 154, 156 formed in the first region 104, second region 106, third region 144, and fourth region 146 of the workpiece 102 in some embodiments. The thickness of the cap layer 114 may optionally be different for p-channel metal oxide semiconductor (PMOS) and n-channel metal oxide semiconductor (NMOS) transistors of the semiconductor device 100, not shown in the drawings. For example, the cap layer 114 may be deposited over the entire workpiece 102, and the workpiece 102 may be masked while a top portion of the cap layer 114 is removed in some regions 104, 106, 144, or 146. Alternatively, the cap layer 114 may be thickened in some regions of the workpiece 102, by depositing or growing additional cap layer 114 material while other regions are masked.

A metal layer 118 is formed over the cap layer 114, as shown in FIG. 8. The metal layer 118 may comprise about 100 nm or less of TiN or TaN in some embodiments, for example. In some embodiments the metal layer 118 comprises about 20 to 100 Å of TiN, TaN, TaCₓ, TaSiNₓ, HfSiₓ, TaSiₓ, NiₓSi_{y}, PtₓSi_{y}, RuOₓcombinations thereof, or a metal doped with Tb, Er, or Yb, as examples. Alternatively, the metal layer 118 may comprise other materials and dimensions. The metal layer 118 may be formed by CVD, PVD, or other methods, as examples. The metal layer 118 comprises a first material layer of a gate 116.

In some embodiments, the metal layer 118 may comprise the same thickness for all of the transistors 124, 126, 154, and 156 formed in the first region 104, second region 106, third region 144, and fourth region 146, respectively, of the workpiece 102. However, in other embodiments, the thickness of the metal layer 118 may be different for at least one transistor 124, 126, 154, 156 formed in the first region 104, second region 106, third region 144, or fourth region 146, respectively, of the workpiece 102. In the embodiment shown in FIG. 8, the metal layer 118 comprises a greater thickness d₂ in regions 144 and 146 than the thickness d₁ of the metal layer 118 in regions 104 and 106.

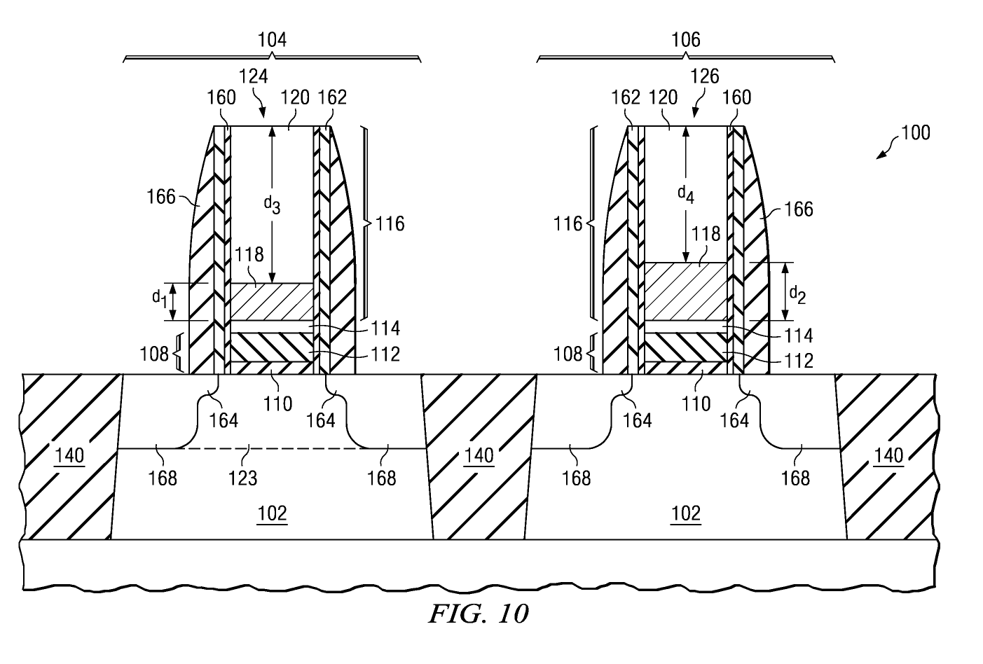

In some embodiments, the thickness d₁ of the metal layer 118 of the first transistor 124 in the first region 104 may be reduced, to tune the threshold voltage of the first transistor 124 due to the presence of the cap layer 114 which is used to tune the second transistor 126 in the second region 106, for example (see FIG. 10). In other embodiments, the thickness d₁ of the metal layer 118 of the first transistor 124 in the first region 104 may be increased to tune the threshold voltage.

Referring again to FIG. 8, to reduce the thickness of the metal layer 118, portions of the metal layer 118 may be masked, and then the unmasked metal layer 118 may be exposed to an etch process to remove a top portion of the metal layer 118 in some regions 104, 106, 144, or 146. Alternatively, additional metal material may be deposited over the unmasked metal layer 118. The masking material then is removed and in a lift-off method, the additional metal material is removed from the masked regions, leaving a metal layer 118 that has a greater thickness d₂ in some regions 144 and 146 than the thickness d₁ of the metal layer 118 in other regions 104 and 106. The different thicknesses d₁ and d₂ of the metal layer 118 result in a change in or a tuning of the threshold voltage values of the transistors 124, 126, 154, and 156 to achieve or establish predetermined threshold voltages for the transistors 124, 126, 154, and 156. As shown in the graph in FIG. 2, the metal layer 118 thickness can be varied to tune the threshold voltage of the transistors 124, 126, 154, and 156 formed in regions 104, 106, 144, or 146, respectively.

Next, a semiconductive material 120 is formed or deposited over the metal layer 118, as shown in FIG. 8. The semiconductive material 120 comprises a second material layer of a gate 116. The semiconductive material 120 may comprise about 700 Å or less of a semiconductive material such as amorphous silicon, polysilicon, or combinations or multiple layers thereof, although alternatively, the semiconductive material 120 may comprise other dimensions and semiconductor materials. In some embodiments, the semiconductive material 120 may comprise a thickness of about 400 to 600 Å, as an example. The semiconductive material 120 may be formed by CVD, PVD, or other methods, as examples. The semiconductive material 120 may optionally be implanted with dopants; e.g., the semiconductive material 120 may be pre-doped or may be doped later, at the same time source and drain regions 164/168 (see FIG. 10) of the transistors 124, 126, 154, and 156 are implanted with dopants.

In some embodiments, the semiconductive material 120 may comprise the same thickness for all of the transistors 124, 126, 154, 156 formed in the first region 104, second region 106, third region 144, and fourth region 146, respectively, of the workpiece 102, not shown. However, in other embodiments, the thickness of the semiconductive material 120 may be different for at least one transistor 124, 126, 154, 156 formed in the first region 104, second region 106, third region 144, or fourth region 146, respectively, of the workpiece 102. In the embodiment shown in FIG. 8, the semiconductive material 120 comprises a greater thickness d₃ in regions 104 and 106 than the thickness d₄ of the semiconductive material 120 in regions 144 and 146.

In some embodiments, the thickness d₃ of the semiconductive material 120 of the first transistor 124 in the first region 104 may be increased, to tune the threshold voltage of the first transistor 124 due to the presence of the cap layer 114 which is used to tune the second transistor 126 in the second region 106, for example (see FIG. 10). In other embodiments, the thickness d₃ of the semiconductive material 120 of the first transistor 124 in the first region 104 may be reduced to tune the threshold voltage of the first transistor 124.

To achieve different thicknesses d₃ and d₄ for the transistors 124 and 126 and transistors 154 and 156, respectively, the nature of the deposition process of the semiconductive material 120 may be used in some embodiments. For example, in FIG. 8, the deposition process for the semiconductive material 120 is substantially conformal, leaving a relatively flat top surface of the semiconductive material 120 after the deposition process. Because of the presence of the additional dielectric layer 148 in the third region 144 and the fourth region 146, and because the metal layer 118 comprises a greater thickness d₂ in the third and fourth regions 144 and 146 than the thickness d₁ of the metal layer 118 in the first and second regions 104 and 106, the semiconductive material 120 comprises a greater thickness d₃ in the first and second regions 104 and 106 than in the third and fourth regions 144 and 146 where the semiconductive material 120 has thickness d₄.

In some embodiments, the transistors 124, 126, 154, and 156 comprise gates 116 comprised of the metal layer 118 and the semiconductive material 120 that have coplanar top surfaces, as shown in FIG. 8, to facilitate further processing of the semiconductor device 100. In other embodiments, the thickness of the semiconductive material 120 may be altered in some regions 104, 106, 144, and 146 and not altered in other regions by masking some regions 104, 106, 144, and 146 and either etching away a top portion of the semiconductive material 120 or by depositing or growing additional semiconductive material 120 on exposed regions 104, 106, 144, and 146.

The thicknesses d₃ and d₄ of the semiconductive material 120 have an effect on the threshold voltage of the transistors 124, 126, 154, and 156. The different thicknesses d₃ and d₄ of the semiconductive material 120 result in a change in or a tuning of the threshold voltage values of the transistors 124, 126, 154, and 156 to achieve or establish predetermined threshold voltages for the transistors 124, 126, 154, and 156.

After the deposition of the semiconductive material 120 of the gates 116 of the transistors 124, 126, 154, and 156, the material stack comprised of the semiconductive material 120, metal layer 118, cap layer 114, insulating layers 112 and 110, and dielectric layer 148 is patterned using lithography, as shown in FIG. 9. Processing of the semiconductor device 100 is then continued, such as forming sidewall spacers over the patterned material stacks, and forming source and drain regions of the transistors 124, 126, 154, and 156. The semiconductive material 120 may optionally be silicided using a silicidation process, for example, not shown.

Transistors 124 and 126 may comprise different types of transistors than transistors 154 and 156. Transistors 154 and 156 may comprise higher voltage transistors than transistors 124 and 126, for example. Transistors 154 and 156 have a gate dielectric 108 comprising dielectric layer 148, second insulating layer 112, and first insulating layer 110 that is thicker than the gate dielectric 108 of transistors 124 and 126 comprising only the first and second insulating layers 110 and 112. Transistor 124 may comprise an NMOS transistor having a threshold voltage of about +300 mV or less or more, and transistor 126 may comprise a PMOS transistor having a threshold voltage of about −300 mV or less or more, as an example. Transistor 154 may comprise an NMOS transistor having a different threshold voltage than +300 mV, and transistor 156 may comprise a PMOS transistor having a different threshold voltage than -300 mV, as an example. The difference in threshold voltage magnitudes between transistors 124 and 126, and transistors 154 and 156, may range from about 50 mV to about 500 mV. The threshold voltage differences of the transistors 124 and 126 and transistors 154, and 156 may alternatively range by other values, depending on the applications.

The transistors 124 and 126 or transistors 154 and 156 may comprise a number of different threshold voltage transistor types. Additional transistor types may also be formed on the semiconductor device 100. The transistors 124 and 126 or 154 and 156 may comprise high voltage transistor devices having a threshold voltage of about 500 mV, medium voltage transistor devices having a threshold voltage of about 300 mV, low voltage transistor devices having a threshold voltage of about 100 mV, super-low voltage transistor devices having a threshold value of less than about 50 mV, and/or zero voltage transistor devices (also not shown) having a threshold value of about 0 mV, as examples. Alternatively, the threshold voltage ranges of the transistors 124 and 126 or 154 and 156 may comprise other values.

In some embodiments, substantially symmetric threshold voltages of transistors 124 and 126 of the semiconductor device 100 are achieved. Transistor 124 may comprise a threshold value of about +300 mV, and transistor 126 may comprise a threshold voltage of about −300 mV, as an example. Likewise, transistors 154 and 156 may comprise substantially symmetric threshold voltages. Alternatively, transistors 124, 126, 154, and 156 may be formed that have substantially asymmetric threshold voltages, in other embodiments.

FIG. 10 shows a cross-sectional view of a semiconductor device 100 in accordance with another embodiment of the present invention. A thickness of the metal layer 118 of the gate 116, a thickness of the semiconductive material 120 of the gate 116, optionally also an implantation region 123 of a channel region of the first transistor 124, and/or optionally also a doped region in the second insulating layer 112 of the first transistor 124 establishes a first threshold voltage (Vₜ₁) for the first transistor 124, which comprises an NMOS transistor. The implantation region 123 may optionally be used to provide counter doping for the presence of the cap layer 114 in the first transistor 124, for example. The cap layer 114 of the second transistor 126 establishes a second threshold voltage (Vₜ₂) for the second transistor 126. In some embodiments, the threshold voltages Vₜ₁ and Vₜ₂ are symmetric, for example.

After the material stack 120, 118, 114, 112, and 110 is patterned, first sidewall spacers 160/162 are formed on the sidewalls of the material stack 120, 118, 114, 112, and 110. The first sidewall spacers 160/162 may comprise a first layer 160 comprising a nitride such as silicon nitride and a second layer 162 comprising an oxide such as silicon dioxide, as examples. Alternatively, the first sidewall spacers 160/162 may comprise other insulating materials. Shallow implantation regions 164 are implanted into the workpiece 102 in the first region 104 and the second region 106. Second sidewall spacers 166 are formed over the first sidewall spacers 160/162, as shown. Deep implantation regions 168 are then implanted into the workpiece 102 in the first region 104 and the second region 106. The implantation regions 164 and 168 function as source and drain regions 164/168 of the transistors 124 and 126.

Insulating material layers and conductive material layers may be formed over the semiconductor device 100 and patterned to complete the fabrication process. Metallization layers (not shown) may be formed that make electrical contact to the source and drain regions 164/168 and gates 116 and interconnect the various components of the semiconductor device 100. Contacts and bond pads may be coupled to the conductive material layers, and individual die of the workpiece 102 may be singulated and packaged, for example, not shown.

Embodiments of the present invention include semiconductor devices 100 manufactured using the methods described herein. Embodiments of the present invention also include methods of fabricating the semiconductor devices 100 described herein.

Embodiments of the present invention have useful applications in semiconductor device 100 designs that require multiple transistors having various threshold voltages across the surface of a workpiece 102. For example, embodiments of the present invention are advantageous when used in designs that require the use of low leakage transistors, which require high threshold voltages, and also fast transistors, which require a low threshold voltage, on a single chip, for example. Other transistors may also be formed on the same chip having regular or medium levels of threshold voltage, for example, using embodiments of the present invention described herein.

Advantages of embodiments of the present invention include providing novel methods of forming semiconductor devices 100 and structures thereof. Novel methods of tuning and adjusting threshold voltages and work functions of transistors 124, 126, 154, and 156 are described herein. Fewer mask levels and processing steps are required to form transistors 124, 126, 154, and 156 of a semiconductor device 100 that have tunable threshold voltages. Because the cap layer 114 is included in the material stack of all transistors 124, 126, 154, and 156 formed on the semiconductor device, damage to the gate dielectric 108 is avoided. Embodiments of the present invention are easily implementable into existing manufacturing process flows, with a reduced number of processing steps being required to fabricate the semiconductor devices 100.

Although embodiments of the present invention and their advantages have been described in detail, it should be understood that various changes, substitutions and alterations can be made herein without departing from the spirit and scope of the invention as defined by the appended claims. For example, it will be readily understood by those skilled in the art that many of the features, functions, processes, and materials described herein may be varied while remaining within the scope of the present invention. Moreover, the scope of the present application is not intended to be limited to the particular embodiments of the process, machine, manufacture, composition of matter, means, methods and steps described in the specification. As one of ordinary skill in the art will readily appreciate from the disclosure of the present invention, processes, machines, manufacture, compositions of matter, means, methods, or steps, presently existing or later to be developed, that perform substantially the same function or achieve substantially the same result as the corresponding embodiments described herein may be utilized according to the present invention. Accordingly, the appended claims are intended to include within their scope such processes, machines, manufacture, compositions of matter, means, methods, or steps.

What is claimed is:

1. A semiconductor device, comprising:
a first transistor in a first region of a workpiece, the first transistor comprising a gate dielectric, a cap layer disposed over the gate dielectric, and a gate comprising a metal layer disposed over the cap layer and a semiconductive material disposed over the metal layer; and
a second transistor in a second region of the workpiece, the second transistor comprising the gate dielectric, the cap layer disposed over the gate dielectric, and a gate comprising the metal layer disposed over the cap layer and the semiconductive material disposed over the metal layer, wherein a thickness of the metal layer, a thickness of the semiconductive material, an implantation region of a channel region, or a doped region of the gate dielectric of the first transistor achieves a predetermined threshold voltage for the first transistor.

2. The semiconductor device according to claim 1, wherein the cap layer of the first transistor comprises a first material, and wherein the cap layer of the second transistor comprises the first material.

3. The semiconductor device according to claim 1, wherein the cap layer of the first transistor comprises a first thickness, and wherein the cap layer of the second transistor comprises the first thickness.

4. The semiconductor device according to claim 1, wherein the cap layer of the first transistor comprises a first thickness, and wherein the cap layer of the second transistor comprises a second thickness, the second thickness being different than the first thickness.

5. The semiconductor device according to claim 1, wherein the cap layer of the first transistor and the cap layer of the second transistor comprise Al, Al₂O₃, AlN, AlOₓN_{y}, or TiOₓN_{y}.

6. The semiconductor device according to claim 1, wherein the metal layer of the first transistor and the metal layer of the second transistor comprise TiN, TaN, TaCₓ, TaSiNₓ, HfSiₓ, TaSiₓ, NiₓSi_{y}, PtₓSi_{y}, RuOₓ, combinations thereof, or a metal doped with Tb, Er, or Yb.

7. The semiconductor device according to claim 1, wherein the metal layer of the first transistor comprises a first thickness, and wherein the metal layer of the second transistor comprises the first thickness.

8. The semiconductor device according to claim 1, wherein the metal layer of the first transistor comprises a first thickness, wherein the metal layer of the second transistor comprises a second thickness, the second thickness being different than the first thickness.

9. A semiconductor device, comprising:
a first transistor in a first region of a workpiece, the first transistor comprising a gate dielectric, a cap layer disposed over the gate dielectric, and a gate comprising a metal layer disposed over the cap layer and a semiconductive material disposed over the metal layer; and
a second transistor in a second region of the workpiece, the second transistor comprising the gate dielectric, the cap layer disposed over the gate dielectric, and a gate comprising the metal layer disposed over the cap layer and the semiconductive material disposed over the metal layer, wherein a thickness of the metal layer, a thickness of the semiconductive material, an implantation region of a channel region, or a doped region of the gate dielectric of the first transistor establishes a first threshold voltage for the first transistor, and wherein the cap layer of the second transistor establishes a second threshold voltage for the second transistor.

10. The semiconductor device according to claim 9, wherein the semiconductive material of the first transistor and the semiconductive material of the second transistor comprise amorphous silicon, polysilicon, or combinations or multiple layers thereof.

11. The semiconductor device according to claim 9, wherein the semiconductive material of the first transistor comprises a first thickness, and wherein the semiconductive material of the second transistor comprises the first thickness.

12. The semiconductor device according to claim 9, wherein the semiconductive material of the first transistor comprises a first thickness, wherein the semiconductive material of the second transistor comprises a second thickness, the second thickness being different than the first thickness.

13. The semiconductor device according to claim 9, wherein the first region includes a first well region that affects the first threshold voltage of the first transistor, or wherein the second region includes a second well region that affects the second threshold voltage of the second transistor.

14. The semiconductor device according to claim 9, further comprising at least one third transistor in at least one third region of the workpiece, the at least one third transistor comprising the gate dielectric, the cap layer disposed over the gate dielectric, and a gate comprising the metal layer disposed over the cap layer and the semiconductive material disposed over the metal layer, wherein the gate dielectric of the at least one third transistor comprises a greater thickness than a thickness of the gate dielectric of the first transistor or a thickness of the gate dielectric of the second transistor.

15. The semiconductor device according to claim 14, wherein the first transistor, the second transistor, or the at least one third transistor comprise a high voltage device, a medium voltage device, a low voltage device, a super-low voltage device, or a zero voltage device.

16. The semiconductor device according to claim 9, wherein a thickness of the metal layer, a thickness of the semiconductive material, the implantation region of a channel region, and/or the doped region of the gate dielectric of the first transistor establishes the first threshold voltage for the first transistor.

17. A method of manufacturing a semiconductor device, the method comprising:
providing a workpiece, the workpiece having a first region and a second region;
forming a gate dielectric over the workpiece;
forming a cap layer over the gate dielectric;
forming a metal layer over the cap layer;
forming a semiconductive material over the metal layer;
altering a thickness of the metal layer in the first region, altering a thickness of the semiconductive material in the first region, implanting a substance into a channel region of the workpiece in the first region, or forming a doped region in the gate dielectric in the first region; and
patterning the semiconductive material, the metal layer, the cap layer, and the gate dielectric, forming a first transistor in the first region of the workpiece and forming a second transistor in the second region of the workpiece, wherein the altered thickness of the metal layer in the first region, the altered thickness of the semiconductive material in the first region, the implanted substance in the channel region in the first region, or the doped region of the gate dielectric in the first region achieves a predetermined threshold voltage for the first transistor in the first region of the workpiece.

18. The method according to claim 17, wherein forming the gate dielectric comprises forming at least one material layer comprising a dielectric constant (k) of greater than about 3.9.

19. The method according to claim 17, wherein forming the gate dielectric comprises forming a first insulating layer of SiON and forming a second insulating layer of HfSiON, HfO₂, HfSiO, a doped hafnium-based dielectric material, or a Zr-based dielectric material over the first insulating layer of SiON.

20. The method according to claim 17, wherein implanting the substance into the channel region of the workpiece in the first region comprises implanting As or P.

21. The method according to claim 17, wherein forming the first transistor comprises forming an n-channel metal oxide semiconductor (NMOS) transistor, and wherein forming the second transistor comprises forming a p-channel metal oxide semiconductor (PMOS) transistor.

22. The method according to claim 21, wherein forming the NMOS transistor and forming the PMOS transistor comprise forming transistors having substantially symmetric threshold voltages (Vₜ).

23. The method according to claim 21, wherein forming the NMOS transistor and forming the PMOS transistor comprise forming a complementary metal oxide semiconductor (CMOS) device.

24. The method according to claim 17, wherein forming the doped region in the gate dielectric in the first region comprises doping the gate dielectric in the first region with a lanthanide series-based metal.

25. The method according to claim 24, wherein doping the gate dielectric in the first region with the lanthanide series-based metal comprises doping the gate dielectric in the first region with La or LaO.
